(19) United States
(12) Patent Application Publication
(10) Pub. No.: US 2025/0266201 A1
(43) Pub. Date: Aug. 21, 2025

(54) TRANSFORMER PACKAGES HAVING CORE COVERS WITH COIL PORTIONS

(71) Applicant: Allegro MicroSystems, LLC, Manchester, NH (US)

(72) Inventors: Paul A. David, Bow, NH (US); Vijay Mangtani, Nashua, NH (US); Andrew Thompson, Cheshire (GB)

(73) Assignee: Allegro MicroSystems, LLC, Manchester, NH (US)

(21) Appl. No.: 18/443,469

(22) Filed: Feb. 16, 2024

(51) Int. Cl. H01F 27/02; H01F 27/24; H01F 27/28; H01F 41/02; H01L 23/00; H01L 23/15; H01L 23/31; H01L 23/522; H01L 25/065; H05K 1/18

(52) U.S. Cl. CPC H01F 27/02; H01F 27/24; H01F 27/28; H01F 41/02; H01L 23/15; H01L 23/3121; H01L 23/5227; H01L 25/0655; H05K 1/18; H01L 24/16; H01L 2224/16225; H01L 2924/181

(57) ABSTRACT

Systems, structures, packages, circuits, and methods provide transformer packages with transformers having core covers with coil portions. A first plurality of conductive traces in a substrate forms first portions of first and second transformer coils. A core cover includes a second plurality of conductive traces forming second portions of the transformer coils and configured to extend around a portion of a provided magnetic core. The core covers are configured such that first (primary) and second (secondary) transformer coils are formed when the second plurality of conductive traces is brought into contact with the first plurality of conductive traces. One or more integrated circuits may be included with transformer packages or modules. The packages and modules may include various types of circuits; in some examples, chip packages or modules may include a galvanically isolated gate driver or other high voltage circuit.

### BACKGROUND

Solid state switches typically include a transistor structure. The controlling electrode of the switch, usually referred to as its gate (or base), is typically controlled (driven) by a switch drive circuit, sometimes also referred to as gate drive circuit. Such solid state switches are typically voltage-controlled, turning on when the gate voltage exceeds a manufacturer-specific threshold voltage by a margin, and turning off when the gate voltage remains below the threshold voltage by a margin.

Switch drive circuits typically receive their control instructions from a controller such as a pulse-width-modulated (PWM) controller via one or more switch driver inputs. Switch drive circuits deliver their drive signals directly (or indirectly via networks of active and passive components) to the respective terminals of the switch (gate and source).

Some electronic systems, including ones with solid state switches, have employed galvanic isolation to prevent undesirable DC currents flowing from one side of an isolation barrier to the other. Such galvanic isolation can be used to separate circuits in order to protect users from coming into direct contact with hazardous voltages.

Various transmission techniques are available for signals to be sent across galvanic isolation barriers including optical, capacitive, and magnetic (inductive) coupling techniques. Magnetic coupling typically relies on use of a transformer to magnetically couple circuits on the different sides of the transformer, typically referred to as the primary and secondary sides, while also providing galvanic separation of the circuits.

Transformers used for magnetic-coupling isolation barriers typically utilize a magnetic core to provide a magnetic path to channel flux created by the currents flowing in the primary and secondary sides of the transformer. Magnetic-coupling isolation barriers have been shown to have various drawbacks, including manufacturing problems, for integrated circuit (IC) packages due to the included magnetic core.

### SUMMARY

Aspects of the present disclosure are directed to transformer-based integrated circuit (IC) packages having a cover for a magnetic core, with the cover including coil portions, and related fabrication/construction techniques/methods.

One general aspect of the present disclosure includes a transformer-based integrated circuit (IC) package having a cover for a magnetic core, with the cover including coil portions (partial coil structures). The transformer package may include a substrate having opposed first and second surfaces and including a first plurality of conductive traces; a magnetic core disposed on the first surface of the substrate, where the magnetic core includes a soft ferromagnetic material; and a cover disposed on the first surface of the substrate and covering the magnetic core, where the cover defines a cavity configured to receive the magnetic core, where the cover is configured to provide a space between an interior surface of the cavity and an exterior surface of the magnetic core, and where the cover includes a second plurality of conductive traces; where the first plurality of conductive traces is connected to the second plurality of conductive traces at a plurality of connections, forming first and second coils disposed about the magnetic core, where the first and second coils and magnetic core are configured as a transformer.

Implementations may include one or more of the following features. The transformer package may include a package body including an encapsulant material configured to encapsulate the cover disposed on the first surface of the substrate. The package body may include a molding material. The space may include a gap between the interior surface of the cavity and the exterior surface of the magnetic core. The transformer package may include at least one semiconductor die disposed on the substrate. The at least one semiconductor die may include an integrated circuit (IC). The IC may include a gate driver. The first and second coils are configured as primary and secondary coils in a step-up configuration, and where the gate driver is connected to the secondary coil. The magnetic core may include ferrite. The substrate may include a printed circuit board (PCB). The substrate may include a leadframe. The substrate may include a glass substrate. The substrate may include a ceramic substrate. The cover may include mold material. The cover is pre-formed. One or more of the second plurality of conductive traces are disposed on a surface of the cover.

One general aspect of the present disclosure includes a method of making a transformer package having a cover for a magnetic core, with the cover including coil portions (partial coil structures). The method may include providing a substrate having opposed first and second surfaces and including a first plurality of conductive traces; providing a magnetic core disposed on the first surface of the substrate, where the magnetic core includes a soft ferromagnetic material; and providing a cover disposed on the first surface of the substrate and covering the magnetic core, where the cover defines a cavity configured to receive the magnetic core, where the cover is configured to provide a space between an interior surface of the cavity and an exterior surface of the magnetic core, and where a second plurality of conductive traces is disposed on the cover; where the first plurality of conductive traces is connected to the second plurality of conductive traces at a plurality of connections, forming first and second coils disposed about the magnetic core, where the first and second coils and magnetic core are configured as a transformer, providing a molding material configured to encapsulate the first surface of the substrate, the cover, and the transformer, where the molding material is configured to form a package body.

Implementations may include one or more of the following features. The method may include providing a body including an encapsulant material configured to encapsulate the first surface of the substrate, the cover, and the transformer. The body includes a molding material. The space may include a gap between the interior surface of the cavity and the exterior surface of the magnetic core. The method may include providing at least one semiconductor die disposed on the substrate. The at least one semiconductor die may include an integrated circuit (IC). The IC may include a gate driver. The first and second coils are configured as primary and secondary coils in a step-up configuration. The magnetic core may include ferrite. The substrate may include a printed circuit board (PCB). The substrate may include a leadframe. The substrate may include a glass substrate. The substrate may include a ceramic substrate. The cover may include mold material. The cover is pre-formed. Providing the cover to the first surface of the substrate may include attaching the cover to the substrate using an adhesive. The adhesive may include epoxy. Providing the cover to the first surface of the substrate may include attaching the cover to the substrate using ultrasonic welding. Providing the cover to the first surface of the substrate may include attaching the cover to the substrate using an interference fit between the cover and a receiving surface of the substrate. The cover includes a main body and a cap received by the main body.

One general aspect includes a voltage-isolated (galvanically-isolated) integrated circuit (IC) package having a cover for a magnetic core, with the cover including coil portions (partial coil structures). The voltage-isolated integrated circuit may include a package body including molding material and having an exterior; a substrate disposed within the package body, where the substrate includes opposed first and second surfaces, and where the substrate includes a first plurality of conductive traces; a magnetic core disposed on the first surface of the substrate, where the magnetic core includes a soft ferromagnetic material; a cover disposed on the first surface of the substrate and covering the magnetic core, where the cover defines a cavity configured to receive the magnetic core, where the cover is configured to provide a space between an interior surface of the cavity and an exterior surface of the magnetic core, and where a second plurality of conductive traces is disposed on the cover; where the first plurality of conductive traces is connected to the second plurality of conductive traces at a plurality of connections, forming first and second coils disposed about the magnetic core, where the first and second coils and magnetic core are configured as a transformer; first and second integrated circuits (ICs) connected to the first and second coils, respectively; a first plurality of leads connected to the first IC, where the first plurality of leads includes exposed lead portions accessible on the exterior of the package body; and a second plurality of leads connected to the second IC, where the second plurality of leads includes exposed lead portions accessible on the exterior of the package body.

Implementations may include one or more of the following features. The first and second ICs may be disposed in first and second IC packages, respectively. The second IC may include a gate driver. The transformer is configured as a step-up transformer. The magnetic core may include ferrite. The substrate may include a printed circuit board (PCB). The substrate may include a leadframe. The substrate may include glass. The substrate may include ceramic. The space may include a gap between the interior surface of the cavity and the exterior surface of the magnetic core. The voltage-isolated IC package may include a seal disposed between the cover and the substrate. The seal may include epoxy. The package body includes a molding material. The package body includes a potting material.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed embodiments may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principals of the concepts described herein. Furthermore, embodiments are illustrated by way of example and not limitation in the figures, in which:

FIGS. 1A-1B are diagrams showing bottom perspective and top perspective views, respectively, of an example core cover for a transformer package, in accordance with the present disclosure;

FIG. 2 is a diagram showing an example transformer-based integrated circuit (IC) package having a core cover with coil portions at different stages of fabrication, in accordance with the present disclosure;

FIG. 3 is diagram showing steps in an example method of fabricating the transformer- based integrated circuit (IC) package shown in FIG. 2;

FIG. 4 is a diagram showing an example method of fabricating transformer packages having core covers with coil portions, in accordance with the present disclosure.

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

An aspect of the present disclosure is directed to and includes substrate-based (e.g., substrate mounted) transformers having covers for transformer cores, with the covers including portions of coils used for the transformers. The covers are configured to cover the core while providing a space for the core (e.g., ferrite) to undergo shape changes due to magnetostriction during operation of the transformer. The cover can have sufficient rigidity/stiffness (e.g., resulting from material used and/or geometry) to resist deformation, e.g., due to pressure/force, during fabrication and/or operation of the package. By creating a solid (rigid or semi-rigid) cover for the core it is possible to reduce deleterious and/or undesirable effects on a potted or molded transformer package arising from magnetostriction. The covers also allow precise control of the distance from the cores to the windings to control isolation distance. In some embodiments, a cover can be sealed to a solid surface, e.g., a substrate such as a PCB. In some embodiments, a cap structure can be created and used to seal the system/package. Sealing/attachment can be effected by, e.g., ultrasonic welding, gluing, using an interference fit, etc.

A cover for a magnetic core can be have a shape appropriate to cover a particular or given core, e.g., a shaped adapted to accept or receive a given magnetic core having a particular shape/geometry. A core cover can be sealed to a substrate, (e.g., PCB), which may be a sub-assembly, to prevent encapsulant and/or mold compound ingress during manufacturing process(es). A cover can contain conductive elements to allow electrical conduction. Such electrical connections can have points that allow connection (e.g., soldering, wire-bonding, or welding) to a different or secondary structure (e.g., a PCB, leadframe, substrate, etc.). Such electrical connections can have points that allow mechanical contact (interface) to a secondary structure (a PCB, leadframe, substrate, etc.). For example, such mechanical contact may include, but is not limited to, a click-in or snap-fit contactor or connection. A cover may have a secondary structure that is designed to seal the system (of core within cover as mounted on a secondary structure such as a substrate) before being connected to/in the next step in the process. This can be attached in multiple ways, including ultrasonic welding, adhesives, an interference fit, or such methods. A cover (cap structure) may also have electrically conductive elements (trace elements) to allow the creation of the additional circuit elements. A core can be potted into the cover with the appropriate material to create a sub assembly that is resistance to external restriction. These noted features may be combined in any or various combinations.

Examples and embodiments of the present disclosure are directed to and include systems, structures, circuits, and methods providing transformers and transformer structures that can be used for galvanic isolation (a.k.a., voltage isolation), e.g., for high-voltage applications. In some embodiments, a transformer with a core cover may have, e.g., a step up, a step down, or a power transformer configuration. Some embodiments and examples can include transformer and integrated circuit (IC) packages or modules with transformer having core covers. Some embodiments can include transformer packages having core covers without one or more ICs. Other passive and/or active components may be included in the transformer packages.

The transformer packages and modules may include various types of circuits (e.g., ICs); in some examples, transformer packages with ICs may include a galvanically isolated gate driver or other high voltage circuit, etc. One or more (e.g., first and second) semiconductor die having one or more integrated circuits (a.k.a., “IC die”) can be included in the packages. Such integrated circuits can include, e.g., but are not limited to, high-voltage circuits such as galvanically-isolated gate drivers configured to drive an external gate on a solid-state switch, e.g., a field effect transistor (FET), a metal oxide semiconductor FET (MOSFET), a metal semiconductor FET (MESFET), a gallium nitride FET (GaN FET), a high electron mobility transistor (HEMT), a silicon carbide FET (SIC FET), an insulated gate bipolar transistor (IGBT), or another load.

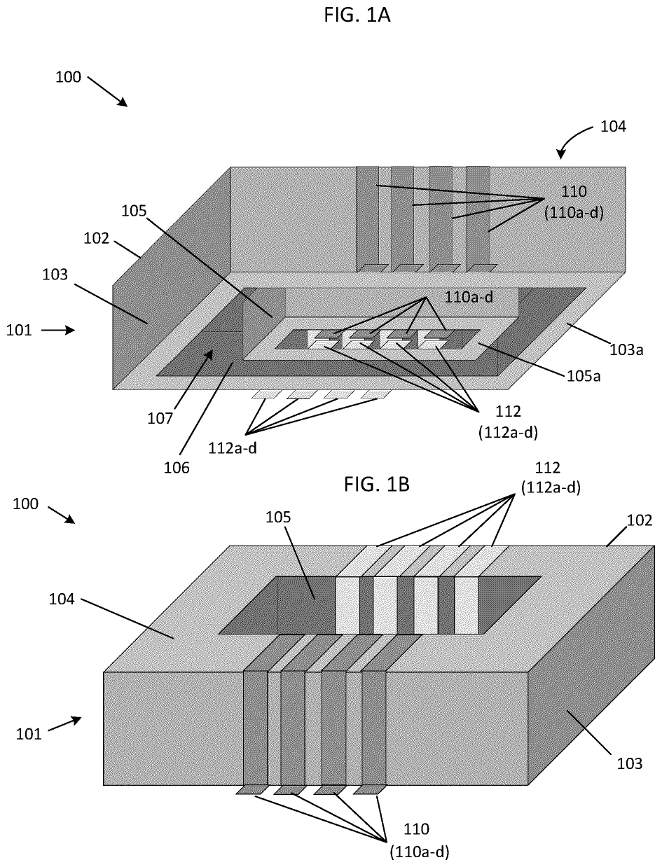

FIGS. 1A-1B are diagrams showing bottom perspective and top perspective views, respectively, of an example core cover 100 for a transformer package, in accordance with the present disclosure.

Cover 100 can include a body 101 with an outer surface 102, an outer wall 103, a top wall 104, an inner wall 105, and an inner surface 106. Inner surface 106 (bounded by walls 103, 104, and 105) forms or defines a cavity 107 that is configured to receive a magnetic core, e.g., of a transformer package in accordance with the present disclosure.

Cover 100 also includes a plurality of conductive traces (indicated as 110 and 112), which as described in further detail below, can form or be used as first portions of coils of a transformer of a transformer package in accordance with the present disclosure. One set of traces 110 includes traces (winding portions) 110a-d while the other set of traces 112 includes traces (winding portions) 112a-d.

Lower surfaces 103a and 105a of outer and inner walls 103 and 105 can be configured to mount to (connect with) a secondary structure, e.g., a substrate such as a PCB, used for a transformer package in accordance with the present disclosure, as described in further detail below.

Cover 100 can have a suitable desired wall thickness (e.g., for any or all of walls 103, 104, and 105). In some embodiments, cover 100 can have a wall thickness that affords an isolation specification equivalent (or thicker) relative to a given desired isolation standard. For example, in some embodiments, a wall thickness of a cover can be 0.4 mm (400 μm) for certain materials and voltage requirements (or a greater or lesser thickness, depending on the requirements).

In some embodiments, cover 100 can be made and configured (“preformed) for a magnetic core having a particular geometry and/or for an underlying structure (e.g., a PCB or other substrate) having a particular geometry (e.g., planar or planar with a sealing structure such a lip, step, or other snap-fit structure, etc.). By preforming (e.g., molding, pressing, and/or shaping) cover 100, a cover 100 can be used as a “preformed” structure that can be mounted to a secondary structure, e.g., a PCB or other substrate, and make a non-mechanically constrained location for the magnetic core. This can then be mounted to the understructure (e.g., PCB) in a method to prevent the next process from filling in the cavity formed by the cover mounted to the understructure.

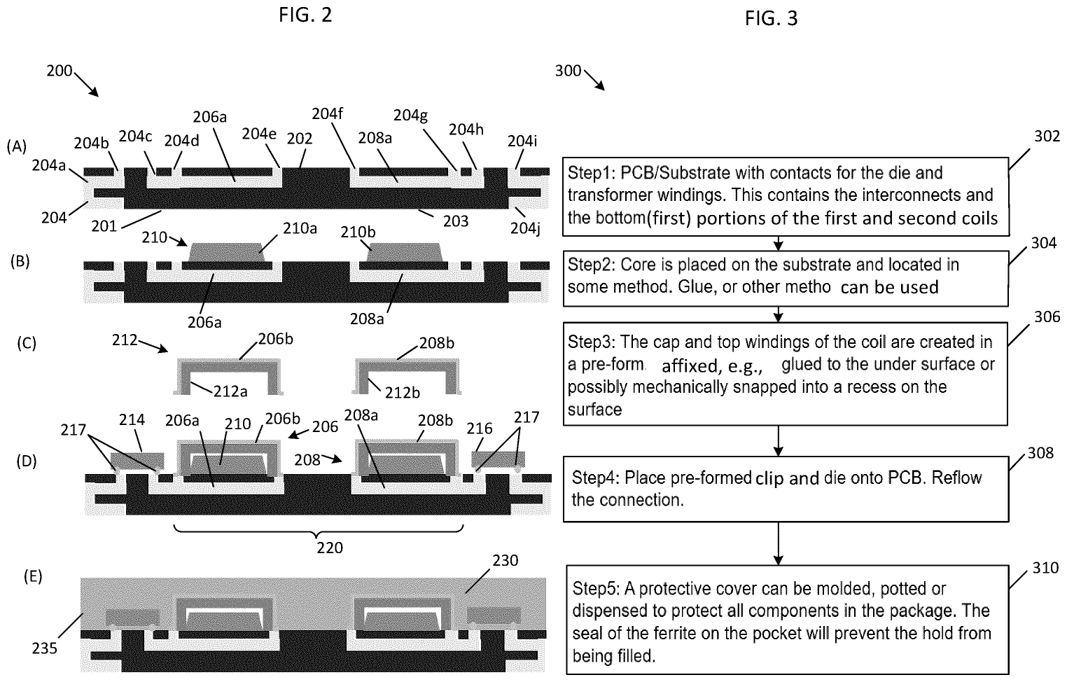

FIG. 2 is a diagram showing structure of an example transformer-based integrated circuit (IC) package 200 having a core cover with coil portions at successive stages of fabrication, in accordance with the present disclosure. The different stages of fabrication of transformer-based (voltage-isolated) IC package 200 are shown in Views A-E.

As shown in View A, structure 200A includes substrate 201 including opposed first and second sides (surfaces) 202, 203 and a plurality of conductive traces (conductive structures) 204, which can be (reside) on a surface of or within substrate 201. In the example shown, conductive traces 204 include conductive traces 204a-204j. As shown, a subset of the plurality of conductive traces 204, can include a plurality (e.g., a “first plurality”) of conductive traces 206a, 208a that form or are used as portions of coils of the package 200, as described in further detail below. Some conductive traces, e.g., 204a and 204j can be used for input/output functionality. Some conductive traces, e.g., 204b-c and 204h-I, can be used for connections to active/passive components such as IC die, etc. Some conductive traces, e.g., 204d-e and 204f-g, can be used for connections to as part of transformer coils, as described in further detail below. Of course, additional conductive structures can be present for substrate 201 in addition to those shown, e.g., in or on one or more portions of substrate 201 extending into and/or out of the drawing plane.

View B shows structure 200B including magnetic core 210 used for transformer 220, shown with cross sections 210a-b, added to structure 200A of View A. While core 210 is shown with a given set (plurality) of conductive traces (i.e., 206a and 208a) in substrate 201 used for windings of two transformer coils, the conductive traces may be configured to present/provide windings for more than two coils (e.g., three, four, etc.) in other embodiments. Core 210 can include one or more soft ferromagnetic materials (e.g., ferrite, a nickel alloy, nickel-iron (NiFe) and/or silicon-iron (SiFe), etc.) and may have a closed shape, e.g., a toroidal or rectangular shape, as indicated. In some embodiments, an insulator material can be provided to the magnetic core to provide isolation. In some embodiments, the core may be insulated with an insulating tape on the core side(s)/surface(s) facing an adjacent substrate.

View C shows core cover 212 with cross sections 212a-b. Cover 212 is can be adapted (sized/shaped appropriately) to cover one or more particular cores 210. Cover 212 can have a closed shape, e.g., similar to cover 100 shown in FIGS. 1A-1B. Cover 212 includes a plurality (e.g., a “second plurality”) of conductive traces 206b, 208b that are used for transformer coils of package 200, as portions of those coils and which are coupled to respective coils portions of substrate 201.

As shown in View D, structure 200D includes cover 212 added to structure 200B of View B. Structure 200D also includes first and second ICs 214, 216 mounted to substrate 201, e.g., as facilitates by conductive structure, e.g., solder balls 217 (which may be subject to a reflow (melting) process), as shown. In some embodiments, either or both of IC 214, 216 can be in a bare semiconductor chip or die (e.g., bare silicon die), and may be bumped or wire-bonded. In other embodiments, either or both of IC 214, 216 can be disposed in a package (e.g., as part of an IC package). Other or different passive and/or active components (not shown) may be added (mounted/connected) to substrate 201. Complete first (primary) and second (secondary) coils 206, 208 are shown, formed from first coil portions 206a and 208a combined with second coil portions 206b and 208b, respectively.

View D shows transformer 220, which includes coils 206, 208 and core 210. It will be understood that while a single coil loop is shown for each of first and second coils 206 and 208, each coil may have one or more additional coil loops, e.g., having a loop pitch into or out of the plane of the figure. Each of the first and second coils 206 and 208 may have a desired number of coil loops (windings). In some embodiments, transformer 220 may be configured as a step up transformer, with secondary coil 208 being on the higher-voltage side. In some embodiments, an IC 214 on the secondary side of transformer 220 can include a gate driver, e.g., configured to drive a solid state power switch such as a FET (e.g., SiC FET or GaN FET) or IGBT, or some other load.

View E of FIG. 2 shows optional encapsulant (encapsulate) material 230 added to structure 200D in View D. Encapsulant 230 may include one or more suitable materials and can form a package body 235, as shown. In some embodiments, encapsulant material 230 can include, but is not limited to, a molding material, a potting material, a dielectric material, and/or the like.

FIG. 3 is diagram showing steps in an example method 300 of fabricating the transformer-based integrated circuit (IC) package shown in FIG. 2. Step 1 of method 300 includes providing a substrate (e.g., a PCB) that has a plurality of conductive traces (e.g., a “first plurality), as described at 302. The plurality of conductive traces can include contacts (contact pads or structures) for passive and/or active components (e.g., IC or IC die) and for transformer windings or portions of transformer windings. The first plurality of conductive traces can include interconnects and portions (first or “bottom” portions) of the first (primary) and second (secondary) coils of the transformer of the transformer package. Step 2 can include affixing (e.g., placing or mounting) a magnetic core to the substrate, as described at 304. Gluing or other suitable techniques/methods may be used for Step 2. Step 3 can include forming (providing) a cover (e.g., cap) with a second plurality of conductive traces-forming portions (second or “top” portions) of the first and second coils, as described at 306. In some embodiments, the cover can be a preformed structure, e.g., made prior to installation/mounting for covering a core on a substrate. Step 4 can include affixing the cover (e.g., cap) to the substrate, as described at 308. Affixing the cover can include creating/completing electrical connection(s) between conductive structures of the substrate and cover, e.g., using a conductive adhesive (conductor with desired adhesive properties). Any suitable affixing technique(s) may be used. In some embodiments, welding, interference-fitting, and/or chemical affixing techniques may be used. Step 4 may include a reflow process in some embodiments.

Optional Step 5 of method 300 can include forming a protective layer (cover layer) to protect the components of the package, as described at 310. Step 5 can result in a complete package with package body. The protective layer can be made of or include one or more encapsulant (encapsulate) materials, including but not limited to molding materials, potting materials, and dielectric materials. In some embodiments, the protective layer may be molded, potted, and/or dispensed.

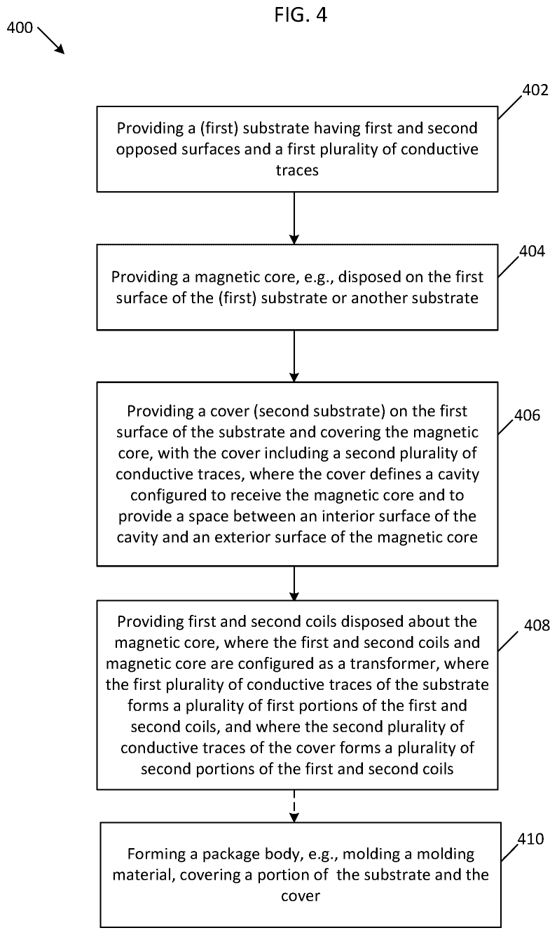

FIG. 4 is a diagram showing an example method 400 of fabricating transformer packages having core covers with coil portions, in accordance with the present disclosure.

Method 400 can include providing a substrate (e.g., a first substrate) having a first plurality of conductive traces, as described at 402. In some embodiments, the substrate may be or include a PCB. A magnetic core can be provided to the substrate, as described at 404. Providing a cover (e.g., a second substrate) on the first surface of the (first) substrate and covering the magnetic core, wherein the cover includes a second plurality of conductive traces, and defines a cavity configured to receive the magnetic core and to provide a space between an interior surface of the cavity and an exterior surface of the magnetic core, as described at 406. In some embodiments, the core can be part of, integral with, and/or joined to the cover (second substrate). Providing first and second coils disposed about the magnetic core, wherein the first and second coils and magnetic core are configured as a transformer, wherein the first plurality of conductive traces of the substrate forms a plurality of first portions of the first and second coils, and wherein the second plurality of conductive traces of the cover forms a plurality of second portions of the first and second coils, as described at 408. In some embodiments, the transformer may be configured as a step up transformer.

A package body can be formed as an optional step, as described at 410. The package body may encapsulate or cover the core and fractional coil structures of the transformer. In some embodiments, one or more IC die (packaged or unpackaged) can be provided to the substrate. For example, in some embodiments first and second IC die can be provided to the substrate prior to the optional encapsulation step (at 410). In some embodiment, the second IC die can include a gate driver.

In some examples and/or embodiments, integrated circuits (ICs), e.g., in IC die 214 and/or 216 in FIG. 2, or other conductive features of the primary and secondary sides of a transformer structure in an IC or transformer package according to the present disclosure can be fabricated or configured to have a desired separation distance (d) between certain parts or features, e.g., to meet internal creepage or external clearance requirements for a given pollution degree rating as defined by certain safety standards bodies such as the Underwriters Laboratories (UL) and the International Electrotechnical Commission (IEC). For example, a separation distance may be between closest (voltage) points of the respective circuits, e.g., the low-voltage (primary) side and high-voltage (secondary) side. For further example, such a separation distance may be the distance between any two voltage points between the primary and secondary sides, e.g., distance between die 214 and die 216 in FIG. 2, or a distance between exposed leads connected to the die, may be or may be at least 1.2 mm, 1.4 mm, 1.5 mm, 3.0 mm, 4.0 mm, 5.5 mm, 7.2 mm, 8.0 mm, 10 mm, or 10+mm in respective examples. Such a distance between conductive portions or areas of die can include any insulation covering a conductor, e.g., such as plastic coating of a wire/lead. Other distances between conductive parts, components, and/or features of an IC/transformer package may also be designed and implemented, e.g., to meet desired internal creepage, voltage breakdown, or external clearance requirements, e.g., between external leads.

In some examples and embodiments, a dielectric material (e.g., gel) may be used for potting and/or protecting substrate (e.g., PCB) systems, assemblies, and/or packages, to protect die, magnetic cores, and/or interconnects from environment conditions (e.g., shocks, vibrations, or other applied forces) and/or to provide dielectric insulation. In some examples, a dielectric material may include, but is not limited to, one or more of the following materials: DOWSIL™ EG-3810 Dielectric Gel (made available by The Dow Chemical Corporation, a.k.a., “Dow”, and DOWSIL™ EG-3896 Dielectric Gel (made available by Dow), which has the ability to provide isolation greater than 20 kV/mm. Other suitable gel materials may also or instead be used, e.g., to meet or facilitate meeting/achieving voltage isolation specifications required by a given package design. DOWSIL™ EG-3810 is designed for temperature ranges from −60° C. to 200° C. and DOWSIL™ EG-3896 Dielectric Gel −40° C. to +185° C.; both of which can be used to meet typical temperature ranges for automotive applications.

Accordingly, embodiments and/or examples of the inventive subject matter can afford various benefits relative to prior art techniques. For example, embodiments and examples of the present disclosure can enable or facilitate use of smaller size packages for a given power, current. or voltage rating. Embodiments and examples of the present disclosure can enable or facilitate lower costs and higher scalability for manufacturing of IC packages/modules having voltage- isolated (galvanic isolation) IC die and transformers.

Various embodiments of the concepts, systems, devices, structures, and techniques sought to be protected are described above with reference to the related drawings. Alternative embodiments can be devised without departing from the scope of the concepts, systems, devices, structures, and techniques described. For example, while coils having a whole number of turns (loops or windings about a related core) may be referenced or described for the drawings, in some embodiments, one or more transformer coils may have a fractional number of turns (loops or windings about a related core), e.g., 1.5, 2.5, 1.75, 1.8, 2.25, 5, 6.5, 8.8, etc.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration.” Any embodiment or design described as “exemplary” is not necessarily to be construed as preferred or advantageous over other embodiments or designs. The terms “one or more,” “plurality,” and “at least one” may indicate any integer number greater than or equal to one, i.e., one, two, three, four, etc.; those terms, however, may refer to fractional numbers/values where context admits, e.g., a number of loops in a transformer coil may be a plurality that includes a fractional value, e.g., 2.75, 3.5, 4.25, etc. The term “connection” can include an indirect connection and a direct connection.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within ±20% of a target (or nominal) value in some embodiments, within plus or minus (±) 10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and implemented in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. A transformer package comprising:
a substrate having opposed first and second surfaces and including a first plurality of conductive traces;
a magnetic core disposed on the first surface of the substrate, wherein the magnetic core includes a soft ferromagnetic material; and
a cover disposed on the first surface of the substrate and covering the magnetic core, wherein the cover defines a cavity configured to receive the magnetic core, wherein the cover is configured to provide a space between an interior surface of the cavity and an exterior surface of the magnetic core, and wherein the cover includes a second plurality of conductive traces;
wherein the first plurality of conductive traces is connected to the second plurality of conductive traces at a plurality of connections, forming first and second coils disposed about the magnetic core, wherein the first and second coils and magnetic core are configured as a transformer.

2. The transformer package of claim 1, further comprising a package body including an encapsulant material configured to encapsulate the cover disposed on the first surface of the substrate.

3. The transformer package of claim 2, wherein the package body comprises a molding material.

4. The transformer package of claim 1, wherein the space comprises a gap between the interior surface of the cavity and the exterior surface of the magnetic core.

5. The transformer package of claim 1, further comprising at least one semiconductor die disposed on the substrate.

6. The transformer package of claim 5, wherein the at least one semiconductor die comprises an integrated circuit (IC).

7. The transformer package of claim 6, wherein the IC comprises a gate driver.

8. The transformer package of claim 7, wherein the first and second coils are configured as primary and secondary coils in a step-up configuration, and wherein the gate driver is connected to the secondary coil.

9. The transformer package of claim 1, wherein the magnetic core comprise ferrite.

10. The transformer package of claim 1, wherein the substrate comprises a printed circuit board (PCB).

11. The transformer package of claim 1, wherein the substrate comprises a leadframe.

12. The transformer package of claim 1, wherein the substrate comprises a glass substrate.

13. The transformer package of claim 1, wherein the substrate comprises a ceramic substrate.

14. The transformer package of claim 1, wherein the cover comprises mold material.

15. The transformer package of claim 14, wherein the cover is pre-formed.

16. The transformer package of claim 1, wherein one or more of the second plurality of conductive traces are disposed on a surface of the cover.

17. A method of making a transformer package, the method comprising:
providing a substrate having opposed first and second surfaces and including a first plurality of conductive traces;
providing a magnetic core disposed on the first surface of the substrate, wherein the magnetic core includes a soft ferromagnetic material; and
providing a cover disposed on the first surface of the substrate and covering the magnetic core, wherein the cover defines a cavity configured to receive the magnetic core, wherein the cover is configured to provide a space between an interior surface of the cavity and an exterior surface of the magnetic core, and wherein a second plurality of conductive traces is disposed on the cover;
wherein the first plurality of conductive traces is connected to the second plurality of conductive traces at a plurality of connections, forming first and second coils disposed about the magnetic core, wherein the first and second coils and magnetic core are configured as a transformer,
providing a molding material configured to encapsulate the first surface of the substrate, the cover, and the transformer, wherein the molding material is configured to form a package body.

18. The method of claim 17, further comprising providing a body including an encapsulant material configured to encapsulate the first surface of the substrate, the cover, and the transformer.

19. The method of claim 18, wherein the body includes a molding material.

20. The method of claim 17, wherein the space comprises a gap between the interior surface of the cavity and the exterior surface of the magnetic core.

21. The method of claim 17, further comprising providing at least one semiconductor die disposed on the substrate.

22. The method of claim 21, wherein the at least one semiconductor die comprises an integrated circuit (IC).

23. The method of claim 22, wherein the IC comprises a gate driver.

24. The method of claim 17, wherein the first and second coils are configured as primary and secondary coils in a step-up configuration.

25. The method of claim 17, wherein the magnetic core comprise ferrite.

26. The method of claim 17, wherein the substrate comprises a printed circuit board (PCB).

27. The method of claim 17, wherein the substrate comprises a leadframe.

28. The method of claim 17, wherein the substrate comprises a glass substrate.

29. The method of claim 17, wherein the substrate comprises a ceramic substrate.

30. The method of claim 17, wherein the cover comprises mold material.

31. The method of claim 17, wherein the cover is pre-formed.

32. The method of claim 17, wherein providing the cover to the first surface of the substrate comprises attaching the cover to the substrate using an adhesive.

33. The method of claim 32, wherein the adhesive comprises epoxy.

34. The method of claim 17, wherein providing the cover to the first surface of the substrate comprises attaching the cover to the substrate using ultrasonic welding.

35. The method of claim 17, wherein providing the cover to the first surface of the substrate comprises attaching the cover to the substrate using an interference fit between the cover and a receiving surface of the substrate.

36. The method of claim 17, wherein the cover includes a main body and a cap received by the main body.

37. A voltage-isolated integrated circuit (IC) package comprising:
a package body including molding material and having an exterior;
a substrate disposed within the package body, wherein the substrate includes opposed first and second surfaces, and wherein the substrate includes a first plurality of conductive traces;
a magnetic core disposed on the first surface of the substrate, wherein the magnetic core includes a soft ferromagnetic material;
a cover disposed on the first surface of the substrate and covering the magnetic core, wherein the cover defines a cavity configured to receive the magnetic core, wherein the cover is configured to provide a space between an interior surface of the cavity and an exterior surface of the magnetic core, and wherein a second plurality of conductive traces is disposed on the cover;
wherein the first plurality of conductive traces is connected to the second plurality of conductive traces at a plurality of connections, forming first and second coils disposed about the magnetic core, wherein the first and second coils and magnetic core are configured as a transformer;
first and second ICs connected to the first and second coils, respectively;
a first plurality of leads connected to the first IC, wherein the first plurality of leads includes exposed lead portions accessible on the exterior of the package body; and
a second plurality of leads connected to the second IC, wherein the second plurality of leads includes exposed lead portions accessible on the exterior of the package body.

38. The voltage-isolated IC package of claim 37, wherein the first and second ICs are disposed in first and second IC packages, respectively.

39. The voltage-isolated IC package of claim 37, wherein the second IC comprises a gate driver.

40. The voltage-isolated IC package of claim 37, wherein the transformer is configured as a step-up transformer.

41. The voltage-isolated IC package of claim 37, wherein the magnetic core comprises ferrite.

42. The voltage-isolated IC package of claim 37, wherein the substrate comprises a printed circuit board (PCB).

43. The voltage-isolated IC package of claim 37, wherein the substrate comprises a leadframe.

44. The voltage-isolated IC package of claim 37, wherein the substrate comprises glass.

45. The voltage-isolated IC package of claim 37, wherein the substrate comprises ceramic.

46. The voltage-isolated IC package of claim 37, wherein the space comprises a gap between the interior surface of the cavity and the exterior surface of the magnetic core.

47. The voltage-isolated IC package of claim 37, further comprising a seal disposed between the cover and the substrate.

48. The voltage-isolated IC package of claim 47, wherein the seal comprises epoxy.

49. The voltage-isolated IC package of claim 37, wherein the package body includes a molding material.

50. The voltage-isolated IC package of claim 37, wherein the package body includes a potting material.
